(19) United States
(12) Patent Application Publication
(10) Pub. No.: US 2019/0305075 A1
(43) Pub. Date: Oct. 3, 2019

(54) SEMICONDUCTOR DEVICE AND METHOD OF MANUFACTURING THE SAME

(71) Applicant: ABLIC Inc., Chiba-shi (JP)

(72) Inventor: Hiroaki TAKASU, Chiba-shi (JP)

(21) Appl. No.: 16/356,349

(22) Filed: Mar. 18, 2019

(30) Foreign Application Priority Data
Mar. 27, 2018 (JP) 2018-060318

(51) Int. Cl. H01L 49/02; H01L 21/02; H01L 21/265; H01L 21/266; H01L 21/308

(52) U.S. Cl. CPC H01L 28/20; H01L 21/02532; H01L 21/02595; H01L 21/308; H01L 21/26513; H01L 21/266; H01L 21/02488

(57) ABSTRACT

A thin film resistor includes a high-resistance region and low-resistance regions which are formed at both ends of the high-resistance region. The high-resistance region includes first high-resistance regions and a second high-resistance region, and the first high-resistance regions are formed to be in contact with both ends of the second high-resistance region formed in a rectangular shape in a transverse direction (first direction) of the second high-resistance region. In a longitudinal direction (second direction) orthogonal to the transverse direction, the first high-resistance regions have the same length as that of the second high-resistance region, and both end surfaces of the first high-resistance regions in the longitudinal direction are flush with both end surfaces of the second high-resistance region in the longitudinal direction to form flat planes.

### RELATED APPLICATIONS

This application claims priority under 35 U.S.C. §119 to Japanese Patent Application No. 2018-060318 filed on Mar. 27, 2018, the entire content of which is hereby incorporated by reference.

### BACKGROUND OF THE INVENTION

### 1. Field of the Invention

The present invention relates to a semiconductor device, and more particularly, to a semiconductor device including a thin film resistor, and a method of manufacturing a semiconductor device including a thin film resistor.

### 2. Description of the Related Art

In an analog IC such as a voltage detector, a bleeder resistor which generally includes a plurality of polysilicon resistors is used.

For example, in a voltage detector, voltage detection is carried out in an error amplifier by comparing a reference voltage which is generated in a reference voltage circuit with a divided voltage which is divided in a bleeder resistor circuit. Accuracy of the divided voltage divided in the bleeder resistor circuit is therefore highly important. When the accuracy in voltage division by the bleeder resistor circuit is poor, an input voltage to the error amplifier varies so that a predetermined release voltage and a predetermined detection voltage cannot be obtained.

To enhance the accuracy in voltage division by the bleeder resistor circuit, various measures have hitherto been taken. For example, in Japanese Patent Application Laid-open No. H09-321229, in order to manufacture a highly accurate analog IC, potentials of conductors which are mounted on upper surfaces or lower surfaces of the polysilicon resistors are fixed for the purpose of obtaining a highly accurate resistance voltage division ratio, so that a desired resistance (voltage division ratio) is obtained.

As illustrated in FIG. 7, a conventional bleeder resistor circuit includes a plurality of thin film resistors each of which has a high-resistance region 301 and low-resistance regions 303 at both ends thereof to form a basic configuration of a thin film resistor 400. Since each of thin film resistors 401 to 406 of a group of thin film resistors is formed by masks having the same width, it is expected that all the thin film resistors are formed to have the same width. In the group of thin film resistors, however, the width of each of W1 and W6 tends to be reduced as compared with the width of each of W2 to W5. As described above, when a processing variation occurs in each thin film resistor in a semiconductor manufacturing process, it is difficult to obtain the same resistance in the plurality of thin film resistors in the bleeder resistor circuit, and it is difficult to achieve a resistance voltage division ratio required for an analog IC at high accuracy.

### SUMMARY OF THE INVENTION

The present invention has an object to provide thin film resistors which are capable of reducing resistance variations among them to form a highly accurate bleeder resistor circuit in a semiconductor device and a method of manufacturing the semiconductor device including a thin fil resistor.

A semiconductor device according to one embodiment of the present invention employs the following measure.

There is provided a semiconductor device including a semiconductor substrate; an insulating film formed on the semiconductor substrate; first high-resistance regions constructed from a polysilicon film, and formed on the insulating film; a second high-resistance region constructed from the polysilicon film, formed on the insulating film, and having side surfaces in a first direction parallel to a direction of current flow, the side surfaces being sandwiched by the first high-resistance regions; and low-resistance regions constructed from the polysilicon film, formed on the insulating film, and arranged on the side surfaces of the first high-resistance regions and the second high-resistance region in a second direction orthogonal to the first direction, a sheet resistance of the first high-resistance regions being higher than a sheet resistance of the second high-resistance region.

Further, a method of manufacturing a semiconductor device according to another embodiment of the present invention uses the following measure.

There is provided a method of manufacturing a semiconductor device including forming a non-doped polysilicon film on an insulating film formed on a semiconductor substrate; forming a first impurity region of a first conductivity type by implanting impurities into the non-doped polysilicon film in a first ion implantation; forming a second impurity region of the first conductivity type having a higher concentration than a concentration of the first impurity region by performing a second ion implantation using a first resist pattern formed on the polysilicon film as a mask; forming a third impurity region of the first conductivity type having a higher concentration than a concentration of the second impurity region, on the polysilicon film by performing a third ion implantation using a third resist pattern formed on the poly silicon film as a mask; etching the polysilicon film using a second resist pattern on the polysilicon film so as to cover the first impurity region, the second impurity region, and the third impurity region as a mask after the third resist pattern is removed; and forming a thin film resistor including first high-resistance regions, a second high-resistance region, and low-resistance regions by heat-treating the polysilicon film including the first impurity region, the second impurity region, and the third impurity region.

With the use of the above-mentioned measures, in a bleeder resistor circuit having thin film resistors, variations in resistance of the thin film resistors can be reduced. A highly accurate bleeder resistor circuit capable of keeping an accurate voltage division ratio in the bleeder resistor circuit in a semiconductor device can be obtained.

### BRIEF DESCRIPTION OF THE DRAWINGS

FIG. 1A is a plan view of a thin film resistor of a semiconductor device according to the first embodiment of the present invention.

FIG. 1B is a plan view of a group of thin film resistors of the semiconductor device according to the first embodiment.

FIG. 2 is a plan view of a thin film resistor of a semiconductor device according to the second embodiment of the present invention.

FIG. 3A, FIG. 3B, FIG. 3C, and FIG. 3D are sectional views for illustrating a manufacturing process for the thin film resistor of the semiconductor device according to the first embodiment of the present invention.

FIG. 4 is a sectional view for illustrating a manufacturing process for the thin film resistor of the semiconductor device according to the first embodiment of the present invention.

FIG. 5 is a block diagram for illustrating an example of a voltage detector using a bleeder resistor circuit constructed from the thin film resistors according to the present invention.

FIG. 6 is a block diagram for illustrating an example of a voltage regulator using a bleeder resistor circuit constructed from the thin film resistors according to the present invention.

FIG. 7 is a plan view of a group of thin film resistors of a semiconductor device in related art.

### DETAILED DESCRIPTION OF THE PREFERRED EMBODIMENTS

A description is now given of embodiments of the present invention with reference to the accompanying drawings.

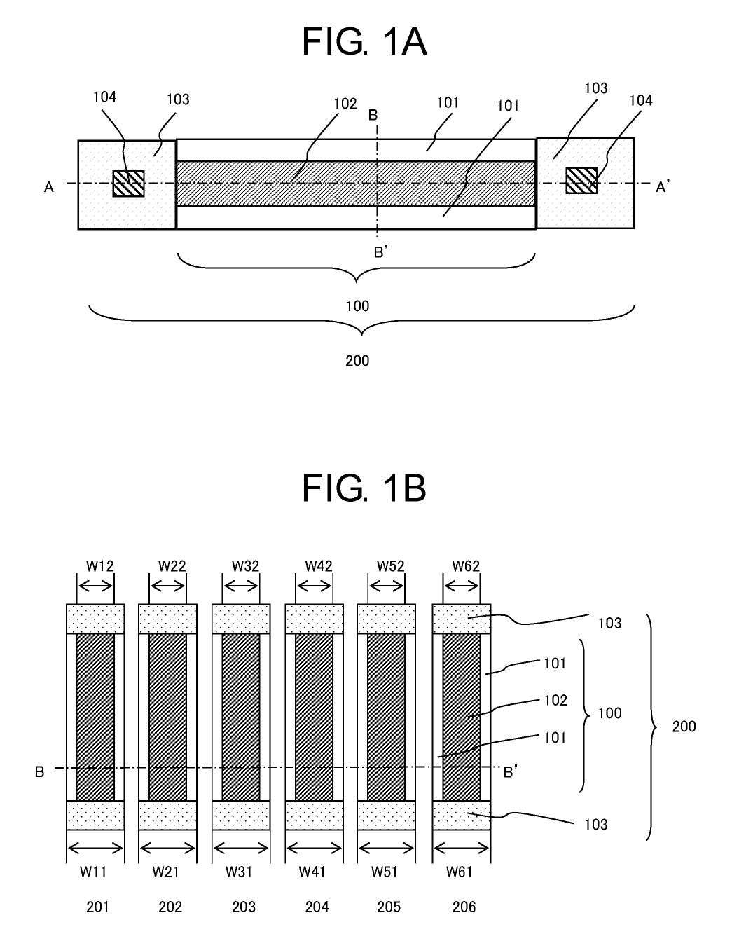

FIG. 1A is a plan view of a thin film resistor of a semiconductor device according to the first embodiment of the present invention, and FIG. 1B is a plan view of a group of thin film resistors of the semiconductor device according to the first embodiment. A basic configuration of a thin film resistor 200 includes a high-resistance region 100 and low-resistance regions 103 which are arranged at both ends of the high-resistance region 100. The high-resistance region 100 includes the first high-resistance regions 101 and the second high-resistance region 102, and the first high-resistance regions 101 are arranged to be in contact with both ends of the second high-resistance region 102 formed in a rectangular shape in a transverse direction (first direction, B-B′ direction) of the second high-resistance region 102. In a longitudinal direction (second direction, A-A′ direction) orthogonal to the transverse direction, the first high-resistance regions 101 have the same length as that of the second high-resistance region 102, and both end surfaces of the first high-resistance regions 101 in the longitudinal direction are substantially flush with both end surfaces of the second high-resistance region 102 in the longitudinal direction. The low-resistance regions 103 are in contact with the planes, that is, with both ends of the high-resistance region 100 in the longitudinal direction.

The first high-resistance regions 101, the second high-resistance region 102, and the low-resistance regions 103 are thin films made from the same layer of a polysilicon film by introducing P-type impurities such as boron. An interlayer insulating film is formed to cover surfaces of the thin film resistor 200 and contact holes 104 are formed in the interlayer insulating film through which the low-resistance regions 103 are partially exposed. The contact holes 104 are used for electrical connection to other resistors, internal circuits, or the like by metal lines.

The first high-resistance regions 101 are formed to have a sheet resistance higher than that of the second high-resistance region 102 by adjusting impurity concentration. To achieve the following advantageous effects more evidently, it is desired that the sheet resistance of the first high-resistance regions 101 is 10 times or more higher than the sheet resistance of the second high-resistance region 102. For example, when the sheet resistance of the second high-resistance region 102 is 5 kΩ/□, the sheet resistance of the first high-resistance regions 101 is set to be 50 kΩ/□ or more.

Further, the first high-resistance regions 101 and the second high-resistance region 102 may be introduced with N-type impurities such as phosphorus and arsenic instead of P-type impurities such as boron to form polysilicon thin film resistors having an N-type conductivity. In addition, to further increase the sheet resistance of the first high-resistance regions 101, the first high-resistance regions 101 may be constructed from a non-doped polysilicon thin film.

Still further, the first high-resistance regions 101 is set to have a width that is double or more the processing variation in semiconductor manufacturing. For example, when the processing variation is plus/minus 0.1 μm, the width of the first high-resistance regions 101 is set to be 0.2 μm or more.

Yet further, the width of the first high-resistance regions 101 is set to be equal to or greater than the width of the second high-resistance region 102. For example, when the width of the second high-resistance region 102 is 1 μm, the width of the first high-resistance regions 101 is set to be 1 μm or more.

A plurality of thin film resistors each of which has been described above are combined to form a bleeder resistor circuit.

According to the embodiment illustrated in FIG. 1A and FIG. 1B, even if the processing variation in the thin film resistor occurs in the manufacturing process for the semiconductor, the variation in resistance of the entire thin film resistor can be suppressed to be small, since a portion at which the processing variation occurs is the first high-resistance regions 101 having a higher sheet resistance.

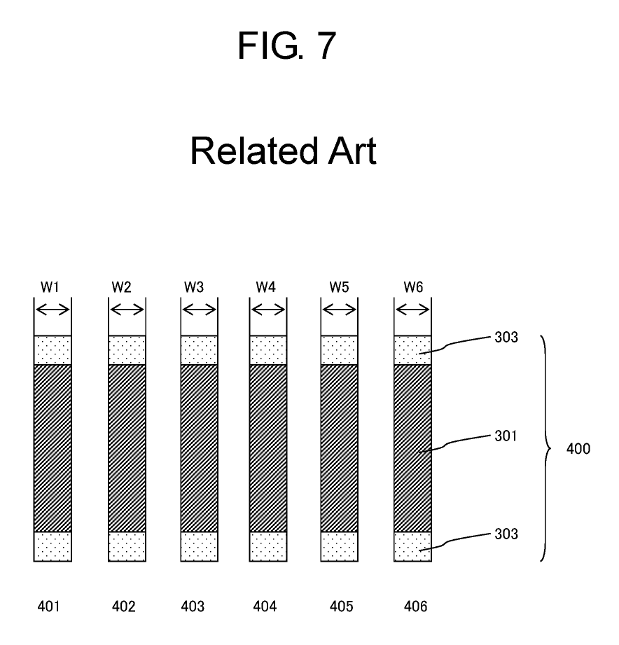

The resistance of the entire thin film resistor is defined by a combination of the first high-resistance regions 101 and the second high-resistance region 102. The sheet resistance of the first high-resistance regions 101 is higher than the sheet resistance of the second high-resistance region 102, and, for example, is set to be 10 times or more higher. Even if the width of the first high-resistance regions 101 varies to some extent due to the processing variation, the influence of the variation is reduced to one tenth or less as compared with the case in which the entire thin film resistor is constructed from the high-resistance region 102 as shown in FIG. 7.

Now, the processing variation in the thin film resistors according to the semiconductor device of the present invention is described as compared with the conventional thin film resistors illustrated in FIG. 7. The widths of the group of thin film resistors 401 to 406 are determined by a photolithography process and an etching process, and it has already been described that the width of each of W1 and W6 is narrower than the width of each of W2 to W5. A factor of the difference in width is a generation of development-accelerating species during development in the photolithography process. When a resist pattern is formed through use of a positive resist, an exposed region is removed with an alkali developing solution (for example, TMAH). At this time, since the alkali developing solution which includes dissolved resist generates development-accelerating species acting to promote the development, a resist pattern for forming the thin film resistors 401 and 406 located at the both ends in the group of thin film resistors is narrower than a resist pattern for forming the thin film resistors 402 to 405. This is because there is a developing region having a large area on one side of the resist pattern for forming the thin film resistors 401 and 406, while there are developing regions having a small area on both sides of the resist pattern for forming the thin film resistors 402 to 405.

As described above, the processing variation occurs because the developing area and the etching area around each thin film resistor are not the same. To suppress the processing variation, the applicant of the present invention therefore proposes a configuration illustrated in FIG. 1B. Thin film resistors 201 to 206 are arranged adjacent with one another, and an outer periphery (outer circumference) of each of the thin film resistors 201 to 206 is formed by the photolithography process and the etching process. Accordingly, one side of the first high-resistance region 101 located at an outer side of the high-resistance region 100 is formed by the photolithography process and the etching process, and the width variations in widths W11 to W61 in a B-B′ direction are the same as those in the conventional thin film resistors. In contrast, in the second high-resistance region 102 located at an inner side of the high-resistance regions 100, the resist pattern to cover the circumference is formed, and then, the resist pattern is used as a mask to form the resistance region by ion implantation. The shape and the size of the region to be developed by the formed resist pattern are therefore the same in all the thin film resistors 201 to 206. As a result, in the photolithography process, the width variations do not occur among the thin film resistors 201 to 206. In the second high-resistance region 102, impurities are introduced in the ion implantation process following the photolithography process, and the region which is subjected to the ion implantation is determined by an opening region of the resist pattern used as a mask. As described above, since the shape and the size of the resist pattern are the same, the width variations of widths W12 to W62 of the second high-resistance regions 102 are unlikely to occur in the thin film resistors 201 to 206.

As described above, the impurities are introduced into the second high-resistance region 102 by the ion implantation, and the first high-resistance regions 101 having a higher resistance than that of the second high-resistance region 102 is formed around the second high-resistance region 102, thereby permitting reduction of the resistance variations among the thin film resistors 201 to 206.

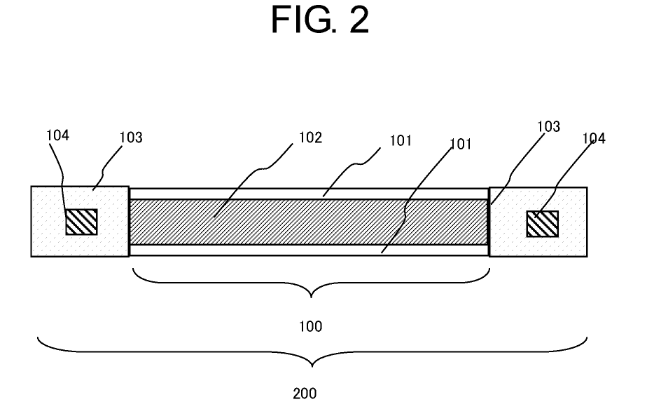

FIG. 2 is a plan view of a thin film resistor of a semiconductor device according to the second embodiment of the present invention in which the width of the first high-resistance regions 101 is reduced due to the processing variation. The resistance of the entire thin film resistor is defined by a combination of the first high-resistance regions 101 and the second high-resistance region 102. The sheet resistance of the first high-resistance regions 101 is set to be 10 times or more higher than the sheet resistance of the second high-resistance region 102. As illustrated in FIG. 2, even if the width of the first resistance regions 101 is reduced due to the processing variation, an influence caused by the reduction in width of the first high-resistance regions 101 can therefore be suppressed to be smaller than the conventional thin film resistor in which the entire thin film resistor is formed of the second high-resistance region 102.

In conventional thin film resistors, for example, when the entire thin film resistor is formed of the second high-resistance region 102 having a width of 1 μm, and the width is reduced by 0.1 μm, a difference in resistance is 10% between the thin film resistor reduced in width and the thin film resistor not reduced in width.

Meanwhile, according to the above-described embodiments, in the case where the thin film resistor is formed by the second high-resistance region 102 having a width of 1 μm and the first high-resistance regions 101 also having a width of 1 μm so as to cover the side surfaces of the second high-resistance region 102, even if the width of the thin film resistor is locally reduced by 0.1 μm due to the variation in manufacturing process, only the first high-resistance regions 101 are reduced in width. Since the sheet resistance of the first high-resistance regions 101 is 10 times or more higher than the sheet resistance of the second high-resistance region 102, the difference in resistance between the thin film resistor reduced in width and the thin film resistor not reduced in width can be greatly reduced to 1% or less.

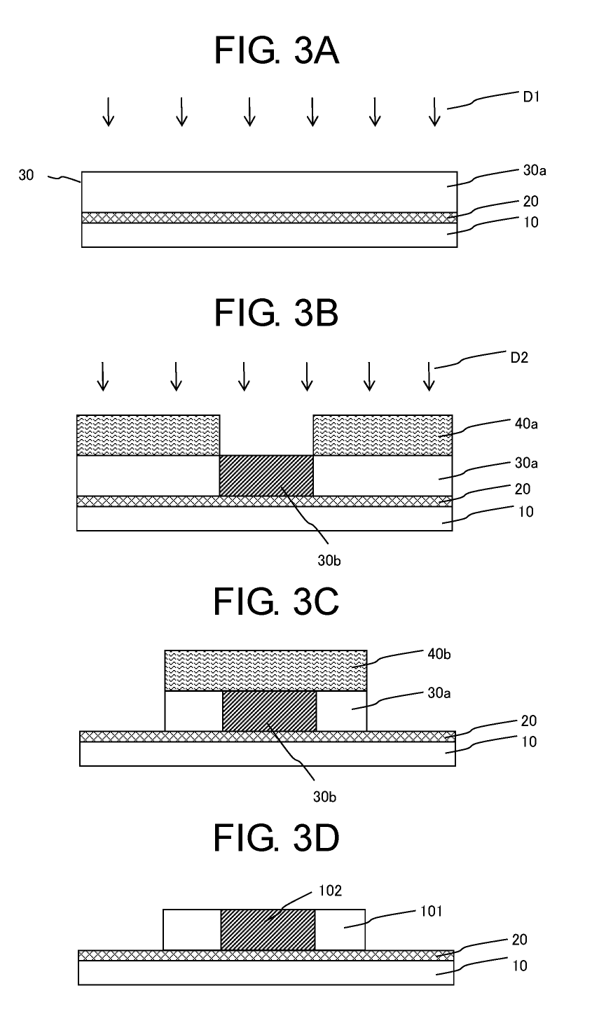

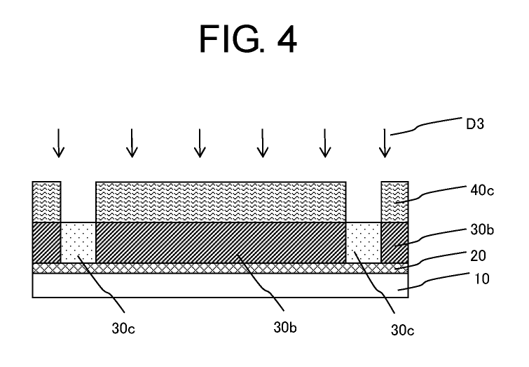

FIG. 3A, FIG. 3B, FIG. 3C, FIG. 3D, and FIG. 4 are sectional views for illustrating a manufacturing process for the thin film resistor of the semiconductor device according to the first embodiment of the present invention. FIG. 3A, FIG. 3B, FIG. 3C, and FIG. 3D are sectional views taken along the transverse direction (B-B′ direction) of FIG. 1A, and FIG. 4 is a sectional view taken along the longitudinal direction (A-A′ direction) of FIG. 1A.

As illustrated in FIG. 3A, an insulating film 20 having a thickness of from 2,000 Å to 8,000 Å is deposited on a semiconductor substrate 10, and then, a non-doped polysilicon film 30 having a thickness of from 500 Å to 2,000 Å is further deposited. Next, P-type impurities such as BF2 are ion-implanted (ion implantation D1) into the polysilicon film 30 to form the first impurity region 30a. When the first impurity region 30a is a non-doped polysilicon film, the ion implantation D1 may be omitted.

Next, as illustrated in FIG. 3B, a resist pattern 40a is formed on the polysilicon film 30. An opening is formed in the resist pattern 40a, and the second high-resistance region 102 is formed later in the opening. The P-type impurities such as BF2 are ion-implanted (ion implantation D2) into the polysilicon film 30 through the opening to form the second impurity region 30b. In the ion implantation D2, impurities are introduced having higher concentration than that of the impurities introduced in the previous ion implantation D1. After the resist pattern 40a is removed, as illustrated in FIG. 4, a resist pattern 40c is formed to expose the regions for the low-resistance regions 103 illustrated in FIG. 1A, and the P-type impurities such as BF2 are ion-implanted (ion implantation D3) into the polysilicon film 30 to form a third impurity region 30c. The impurities implanted at this time have an extremely higher concentration than that of the impurities introduced in the ion-implantation D2, and the dosage at the time of implantation is from 3E15 atoms/cm² to 6E15 atoms/cm².

Although wave-shape surfaces due to the standing wave are formed in side surfaces of the resist pattern 40a, post exposure bake (PEB) is used in this process to alleviate an influence of the standing wave so that a stable width can be obtained.

After the resist pattern 40a is removed, as illustrated in FIG. 3C, a resist pattern 40b is formed to cover the three P-type impurity regions, that is, the first impurity region 30a, the second impurity region 30b, and the third impurity region, and the polysilicon film 30 is etched through use of the resist pattern 40b as a mask. The planar structure of the etched region is as illustrated in FIG. 1A.

After the resist pattern 40b is removed, the polysilicon film having the first impurity region 30a, the second impurity region 30b, and the third impurity region is subjected to heat treatment at from 700° C. to 950° C., which completes the thin film resistor having the first high-resistance regions 101, the second high-resistance region 102, and the low-resistance regions 103. The order of sheet resistances of respective portions forming the thin film resistors 200 thus obtained is, from high to low, the first high-resistance regions 101, the second high-resistance region 102, and the low-resistance 103 regions.

In the above description, forming the P-type resistor has been described. However, when an N-type resistor is formed, phosphorus or arsenic may be selected as ion species.

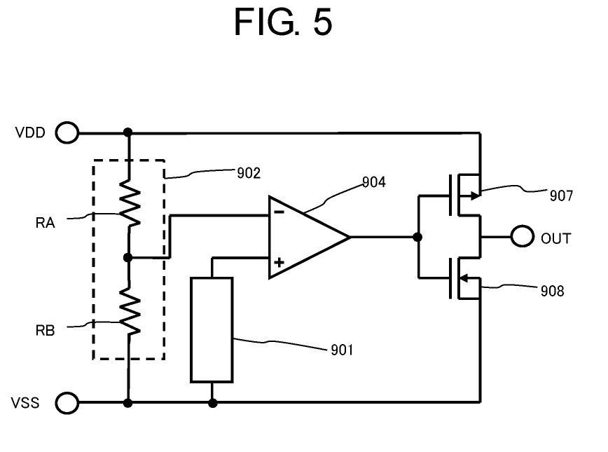

FIG. 5 is a block diagram of a voltage detector using a bleeder resistor circuit constructed from the thin film resistors according to the embodiments of the present invention.

The bleeder resistor circuit having a highly accurate voltage division ratio, which is formed of the plurality of thin film resistors illustrated in FIG. 1A, FIG. 1B, and FIG. 2 according to the embodiments of the present invention, is used so that a highly accurate semiconductor device, for example, a semiconductor device such as a voltage detector and a voltage regulator, can be provided.

In FIG. 5, a simple circuit is illustrated for simplicity, but an actual product may have additional functions as required. Basic circuit components of the voltage detector are a reference voltage circuit 901, a bleeder resistor circuit 902, and an error amplifier 904, and an N-type transistor 908, a P-type transistor 907, and the like are additionally arranged. An operation of the voltage detector is briefly and partially described below.

An inverting input of the error amplifier 904 is a divided voltage Vr, which is divided by the bleeder resistor circuit 902, that is, RB/(RA+RB)×VDD. A reference voltage Vref of the reference voltage circuit 901 is set to be equal to the divided voltage Vr obtained when a power supply voltage VDD is a predetermined detection voltage Vdet. That is, Vref=RB/(RA+RB)×Vdet. When the power supply voltage VDD is equal to or higher than the predetermined voltage Vdet, an output of the error amplifier 904 is designed to be LOW. The P-type transistor 907 is thus turned on and the N-type transistor 908 is turned off, and the power supply voltage VDD is output to an output OUT. Then, when the power supply voltage VDD decreases to be equal to or lower than the detection voltage Vdet, VSS is output to the output OUT.

Thus, in the basic operation, the reference voltage Vref, which is generated in the reference voltage circuit 901, is compared with the divided voltage Vr, which is divided by the bleeder resistor circuit 902, in the error amplifier 904. The accuracy in the divided voltage Vr divided by the bleeder resistor circuit 902 thus becomes extremely important. When the bleeder resistor circuit 902 has poor accuracy in voltage division, the input voltage to the error amplifier 904 varies and a predetermined release voltage and a predetermined detection voltage cannot be obtained. High accuracy voltage division becomes possible by using the bleeder resistor circuit constructed from the thin film resistors according to the embodiments of the present invention, a product yield as an IC can be improved and a more accurate voltage detector can be manufactured.

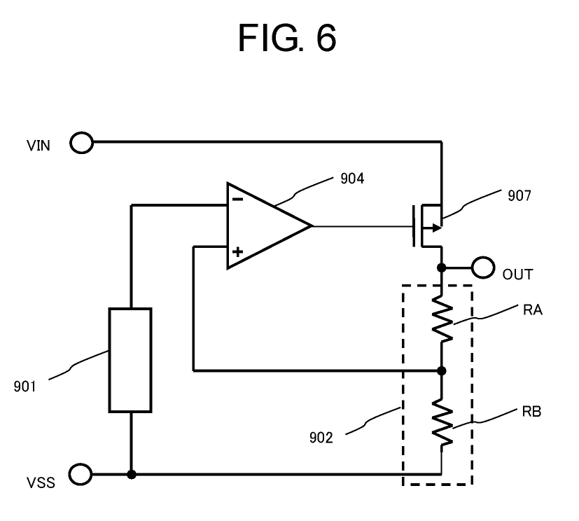

FIG. 6 is a block diagram of a voltage regulator using the bleeder resistor circuit constructed from the thin film resistors according to the embodiments of the present invention.

In FIG. 6, a simple circuit is illustrated for simplicity, but an actual product may have additional functions as required. Basic circuit components of the voltage regulator are the reference voltage circuit 901, the bleeder resistor circuit 902, the error amplifier 904, the P-type transistor 907 acting as a current control transistor, and the like. An operation of the voltage regulator is briefly and partially described below.

The error amplifier 904 compares the divided voltage Vr divided by the bleeder resistor circuit 902 with the reference voltage Vref generated in the reference voltage circuit 901, and applies to the P-type transistor 907 a gate voltage required for obtaining a constant predetermined output voltage VOUT, which is independent of a change in the input voltage VIN. In the voltage regulator as well as the voltage detector described with reference to FIG. 5, in the basic operation, the reference voltage Vref generated in the reference voltage circuit 901 is compared with the divided voltage Vr divided by the bleeder resistor circuit 902 in the error amplifier 904. The accuracy in the divided voltage Vr divided by the bleeder resistor circuit 902 thus becomes extremely important. When the bleeder resistor circuit 902 has poor accuracy in voltage division, the input voltage to the error amplifier 904 varies and a predetermined output voltage Vout cannot be obtained. High accuracy voltage division becomes possible by using the bleeder resistor circuit constructed from the thin film resistors according to the embodiments of the present invention, a product yield as an IC can be improved and a more accurate voltage regulator can be manufactured.

As described above, with the use of the thin film resistor in the present invention, in a manufacturing process for a semiconductor, even if a processing variation in the thin film resistor occurs, the portion suffered from the processing variation is the first high-resistance regions, and hence the resistance variations of the thin film resistor can be suppressed to be small.

What is claimed is:

1. A semiconductor device, comprising:
a semiconductor substrate;
an insulating film formed on the semiconductor substrate;
first high-resistance regions constructed from a polysilicon film, and formed on the insulating film;
a second high-resistance region constructed from the polysilicon film, formed on the insulating film, and having side surfaces in a first direction parallel to a direction of current flow, the side surfaces being sandwiched by the first high-resistance regions; and
low-resistance regions constructed from the polysilicon film, formed on the insulating film, and arranged on the side surfaces of the first high-resistance regions and the second high-resistance region in a second direction orthogonal to the first direction,
a sheet resistance of the first high-resistance regions being higher than a sheet resistance of the second high-resistance region.

2. The semiconductor device according to claim 1, wherein the sheet resistance of the first high-resistance region is 10 times or more higher than the sheet resistance of the second high-resistance region.

3. The semiconductor device according to claim 1, wherein the first high-resistance regions and the second high-resistance region are constructed from the polysilicon film into which impurities of a first conductivity type are introduced.

4. The semiconductor device according to claim 2, wherein the first high-resistance regions and the second high-resistance region are constructed from the polysilicon film into which impurities of a first conductivity type are introduced.

5. The semiconductor device according to claim 1, wherein the first high-resistance regions and the second high-resistance region are constructed from the polysilicon film into which impurities of a second conductivity type are introduced.

6. The semiconductor device according to claim 2, wherein the first high-resistance regions and the second high-resistance region are constructed from the polysilicon film into which impurities of a second conductivity type are introduced.

7. The semiconductor device according to claim 1, wherein the first high-resistance regions are constructed from a non-doped polysilicon film, and the second high-resistance region is constructed from the polysilicon film into which impurities of one of a first conductivity type and a second conductivity type are introduced.

8. A method of manufacturing a semiconductor device, comprising:
forming a non-doped polysilicon film on an insulating film formed on a semiconductor substrate;
forming a first impurity region of a first conductivity type by implanting impurities into the non-doped polysilicon film in a first ion implantation;
forming a second impurity region of the first conductivity type having a higher concentration than a concentration of the first impurity region by performing a second ion implantation using a first resist pattern formed on the polysilicon film as a mask;
forming a third impurity region of the first conductivity type having a higher concentration than a concentration of the second impurity region by performing a third ion implantation using a third resist pattern formed on the polysilicon film as a mask;
etching the polysilicon film using a second resist pattern on the polysilicon film so as to cover the first impurity region, the second impurity region, and the third impurity region as a mask after the third resist pattern is removed; and
forming a thin film resistor including first high-resistance regions, a second high-resistance region, and low-resistance regions by heat-treating the polysilicon film including the first impurity region, the second impurity region, and the third impurity region.
